(19) United States
(12) Patent Application Publication
(10) Pub. No.: US 2026/0011533 A1
(43) Pub. Date: Jan. 8, 2026

(54) PLASMA PROCESSING APPARATUS AND DIELECTRIC WINDOW

(71) Applicant: Tokyo Electron Limited, Tokyo (JP)

(72) Inventors: Mitsunori OHATA, Miyagi (JP); Yohei YAMAZAWA, Miyagi (JP); Mayo UDA, Miyagi (JP)

(73) Assignee: Tokyo Electron Limited, Tokyo (JP)

(21) Appl. No.: 19/249,025

(22) Filed: Jun. 25, 2025

Related U.S. Application Data
(63) Continuation of application No. PCT/JP2023/044546, filed on Dec. 13, 2023.

(30) Foreign Application Priority Data
Dec. 27, 2022 (JP) 2022-209343

(51) Int. Cl. H01J 37/32

(52) U.S. Cl. CPC H01J 37/3244; H01J 37/3211; H01J 37/32119

(57) ABSTRACT

A plasma processing apparatus includes a chamber including a dielectric window constituting an upper part of the chamber and formed therein with a plurality of gas channels, a gas supply section connected to the plurality of gas channels and configured to supply processing gas to the chamber, an antenna assembly that is disposed above the chamber, is set with a first surrounding region, a second surrounding region, and a third surrounding region, and includes a primary coil disposed in the third surrounding region and a secondary coil disposed in the first surrounding region, and an RF power supply configured to supply RF power to at least one of the primary coil and the secondary coil. Each gas channel extends in a radial direction of the dielectric window and is formed so that distances from a gas supply port to gas introduction ports are equal to each other.

### CROSS-REFERENCE TO RELATED APPLICATIONS

This application is a continuation application of International Application PCT/JP2023/044546, filed on Dec. 13, 2023, and designating the U.S., which claims priority to Japanese Patent Application JP 2022-209343, filed on Dec. 27, 2022, the entire contents of each are incorporated herein by reference.

### FIELD

The present disclosure relates to a plasma processing apparatus and a dielectric window.

### BACKGROUND

Disclosed is a plasma processing apparatus including a chamber that accommodates a substrate, a dielectric window that constitutes an upper part of the chamber, a gas supply part that supplies processing gas from the upper part of the chamber into the chamber, an antenna provided above of the chamber and around the gas supply part to generate plasma of the processing gas in the chamber by supplying high frequency waves into the chamber, and a power supply part that supplies high frequency power to the antenna (Patent Literature 1).
Patent Literature 1: Japanese Patent Application Laid-open No. 2019-67503

### SUMMARY

According to an aspect of a present disclosure, a plasma processing apparatus includes: a chamber configured to accommodate a substrate and including a dielectric window constituting an upper part of the chamber and formed therein with a plurality of gas channels; a gas supply section connected to the plurality of gas channels and configured to supply processing gas into the chamber; an antenna assembly that is disposed above the chamber, is set with a central region, a first surrounding region surrounding the central region, a second surrounding region surrounding the first surrounding region, and a third surrounding region surrounding the second surrounding region, and includes a primary coil disposed in the third surrounding region and a secondary coil disposed in the first surrounding region; and a radio frequency (RF) power supply configured to supply RF power to at least one of the primary coil and the secondary coil, wherein each of the plurality of gas channels extends in a radial direction of the dielectric window and is formed so that distances from a gas supply port connected to the gas supply section to gas introduction ports for introducing the processing gas into the chamber are equal to each other.

### BRIEF DESCRIPTION OF DRAWINGS

FIG. 1 is a view illustrating an example of a plasma processing system in one embodiment of the present disclosure.

FIG. 2 is a schematic perspective view illustrating an example of an antenna in the present embodiment.

FIG. 3 is a view illustrating an example of the arrangement of an inner coil and an outer coil in the present embodiment.

FIG. 4 is a top view illustrating an example of a dielectric window in the present embodiment.

FIG. 5 is a graph illustrating an example of the relationship between an angle between a gas channel and the inner coil and an acceleration distance of electrons.

FIG. 6 is a cross-sectional view illustrating an example of the positional relationship between a gas channel and the inner and outer coils.

FIG. 7 is a cross-sectional view illustrating an example of the positional relationship between a gas channel and the inner and outer coils.

FIG. 8 is a cross-sectional view illustrating an example of the positional relationship between a gas channel and the inner and outer coils.

FIG. 9 is a cross-sectional view illustrating an example of the positional relationship between a gas channel and the inner and outer coils.

FIG. 10 is a schematic perspective view illustrating an example of the positional relationship between the gas channel and the inner and outer coils.

FIG. 11 is a cross-sectional view illustrating an example of the positional relationship when radial gas channels overlap in a thickness direction of a dielectric window.

FIG. 12 is a cross-sectional view illustrating an example of a channel near a gas introduction port.

FIG. 13 is a cross-sectional view illustrating an example of a channel near a gas introduction port.

FIG. 14 is a cross-sectional view illustrating an example of a channel near a gas introduction port.

FIG. 15 is a cross-sectional view illustrating an example of the positional relationship between the gas channel and the inner coil.

FIG. 16 is a cross-sectional view illustrating an example of the positional relationship between a gas channel and inner and outer coils.

FIG. 17 is a cross-sectional view illustrating an example of the positional relationship between a gas channel and inner and outer coils.

FIG. 18 is a cross-sectional view illustrating an example of the positional relationship between a gas channel and inner and outer coils.

FIG. 19 is a cross-sectional view illustrating an example of the positional relationship between a gas channel and an inner coil.

FIG. 20 is a cross-sectional view illustrating an example of the positional relationship between a gas channel and inner and outer coils.

FIG. 21 is a cross-sectional view illustrating an example of the positional relationship between a gas channel and inner and outer coils.

### DESCRIPTION OF EMBODIMENT

Embodiments of a plasma processing apparatus and a dielectric window that are disclosed are described below with reference to the drawings. The disclosed technology is not limited by the following embodiments.

An inductively coupled plasma (ICP)-type plasma processing apparatus has a dielectric window and a coiled antenna at the top of a chamber to generate an induced electric field in the chamber. Therefore, processing gas is introduced into the chamber by using either a gas injector provided at the center of the dielectric window, avoiding the antenna, or a gas injector provided on a sidewall of the chamber. However, these gas injectors do not provide sufficient in-plane uniformity of the processing gas. In a case where a gas shower is used, when a diffusion space of the processing gas is directly below a coil of the antenna, abnormal discharge may occur in the diffusion space. In this regard, evenly supplying the processing gas while suppressing abnormal discharge is expected.

### Configuration of Plasma Processing System

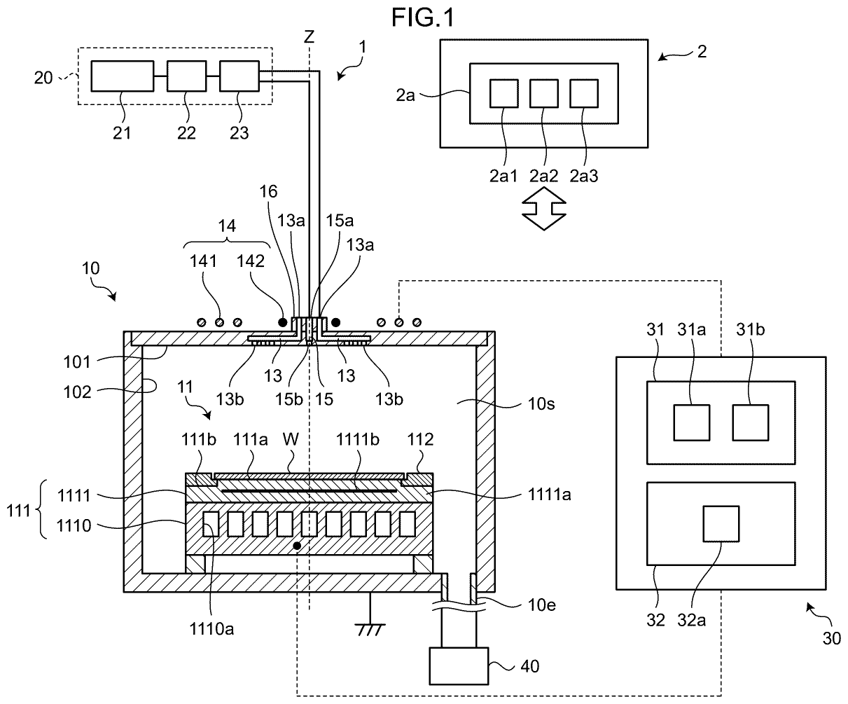

An example of a configuration of a plasma processing system is described below. FIG. 1 is a view illustrating an example of the plasma processing system in one embodiment of the present disclosure. As illustrated in FIG. 1, the plasma processing system includes an inductively coupled plasma processing apparatus 1 and a controller 2. The inductively coupled plasma processing apparatus 1 includes a plasma processing chamber 10, a gas supply section 20, a power supply 30, and an exhaust system 40. The plasma processing chamber 10 includes a dielectric window 101. The plasma processing apparatus 1 also includes a substrate support 11, a gas introduction section 16, and an antenna 14. The substrate support 11 is disposed in the plasma processing chamber 10. The antenna 14 is disposed on or above the plasma processing chamber 10 (that is, on or above the dielectric window 101). The plasma processing chamber 10 has a plasma processing space 10s defined by the dielectric window 101, sidewalls 102 of the plasma processing chamber 10, and the substrate support 11. The plasma processing chamber 10 has at least one gas supply port for supplying at least one processing gas to the plasma processing space 10s and at least one gas discharge port for discharging the gas from the plasma processing space 10s. The plasma processing chamber 10 is grounded.

The substrate support 11 includes a body 111 and a ring assembly 112. The body 111 has a central region 111a for supporting a substrate W and an annular region 111b for supporting the ring assembly 112. A wafer is an example of the substrate W. The annular region 111b of the body 111 surrounds the central region 111a of the body 111 in plan view. The substrate W is disposed on the central region 111a of the body 111, and the ring assembly 112 is disposed on the annular region 111b of the body 111 to surround the substrate W on the central region 111a of the body 111. Accordingly, the central region 111a is also referred to as a substrate support surface for supporting the substrate W, and the annular region 111b is also referred to as a ring support surface for supporting the ring assembly 112.

In one embodiment, the body 111 includes a base 1110 and an electrostatic chuck 1111. The base 1110 includes a conductive member. The conductive member of the base 1110 can serve as a bias electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Other members surrounding the electrostatic chuck 1111, such as an annular electrostatic chuck or an annular insulating member, may have the annular region 111b. In this case, the ring assembly 112 may be disposed on the annular electrostatic chuck or the annular insulating member, or on both the electrostatic chuck 1111 and the annular insulating member. At least one radio frequency (RF)/direct current (DC) electrode coupled to an RF power supply 31 and/or a DC power supply 32 to be described later may be disposed in the ceramic member 1111a. In this case, at least one RF/DC electrode serves as a bias electrode. The conductive member of the base 1110 and at least one RF/DC electrode may serve as a plurality of bias electrodes. The electrostatic electrode 1111b may also serve as a bias electrode. Accordingly, the substrate support 11 includes at least one bias electrode.

The ring assembly 112 includes one or more annular members. In one embodiment, the one or more annular members include one or more edge rings and at least one cover ring. The edge ring is made of a conductive material or an insulating material, and the cover ring is made of an insulating material.

The substrate support 11 may also include a temperature adjusting module configured to regulate at least one of the electrostatic chuck 1111, the ring assembly 112, and the substrate to a target temperature. The temperature adjusting module may include a heater, a heat transfer medium, a channel 1110a, or a combination thereof. A heat transfer fluid such as brine or gas flows through the channel 1110a. In one embodiment, the channel 1110a is formed in the base 1110 and one or more heaters are disposed in the ceramic member 1111a of the electrostatic chuck 1111. The substrate support 11 may also include a heat transfer gas supply section configured to supply heat transfer gas to a gap between the backside of the substrate W and the central region 111a.

The dielectric window 101 is formed therein with a plurality of gas channels 13 and a gas channel 15 at a central portion thereof. The dielectric window 101 is made of a dielectric material such as quartz, alumina, or other ceramics. Each of the plurality of gas channels 13 extends in the radial direction of the dielectric window 101. That is, each of the plurality of gas channels 13 is formed radially from near the center of the dielectric window 101. The dielectric window 101 is formed at the center thereof with the gas introduction section 16 and includes gas supply ports 13a of the plurality of gas channels 13 and a gas supply port 15a of the gas channels 15. Each of the plurality of gas channels 13 is formed so that distances from the gas supply ports 13a to gas introduction ports 13b into the plasma processing chamber 10 are equal to each other. Each gas introduction port 13b is provided at a position that does not overlap an outer coil 141 and an inner coil 142 to be described later of the antenna 14 in a longitudinal direction (for example, direction along an Z axis in FIG. 1). The gas channel 15 has a gas introduction port 15b on the plasma processing space 10s side. The gas introduction section 16 is configured to introduce at least one processing gas from the gas supply section 20 into the plasma processing space 10s via the gas channels 13 and 15. The gas channel 15 may be omitted.

The gas supply section 20 may include at least one gas source 21, at least one flow controller 22, and at least one flow splitter 23. In one embodiment, the gas supply section 20 is configured to supply at least one processing gas from a corresponding gas source 21 to the gas introduction section 16 via corresponding flow controller 22 and flow splitter 23. Each flow controller 22 may include, for example, a mass flow controller or a pressure-controlled flow controller. The flow splitter 23 splits the flow of the processing gas to each of the gas channels 13 and 15. Moreover, the gas supply section 20 may include one or more flow modulation devices that modulate or pulse the flow of at least one processing gas. The flow splitter 23 may be omitted when the gas channel 15 is omitted or when the processing gas is supplied to the gas channels 13 and 15 collectively.

The power supply 30 includes the RF power supply 31 coupled to the plasma processing chamber 10 via at least one impedance matching circuit. The RF power supply 31 is configured to supply at least one RF signal (RF power) to at least one bias electrode and the antenna 14. This forms plasma from at least one processing gas supplied to the plasma processing space 10s. Accordingly, the RF power supply 31 can serve as at least a part of a plasma generator configured to generate plasma from one or more processing gases in the plasma processing chamber 10. By supplying a bias RF signal to at least one bias electrode, a bias potential is generated on the substrate W, and ions in the formed plasma can be attracted to the substrate W.

In one embodiment, the RF power supply 31 includes a first RF generator 31a and a second RF generator 31b. The first RF generator 31a is coupled to the antenna 14 and configured to generate a source RF signal (source RF power) for plasma generation via at least one impedance matching circuit. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to the antenna 14.

The second RF generator 31b is coupled to at least one bias electrode via at least one impedance matching circuit and configured to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one bias electrode. In various embodiments, at least one of the source RF signal and the bias RF signal may be pulsed.

The power supply 30 may also include the DC power supply 32 coupled to the plasma processing chamber 10. The DC power supply 32 includes a bias DC generator 32a. In one embodiment, the bias DC generator 32a is connected to at least one bias electrode and configured to generate a bias DC signal. The generated bias DC signal is applied to at least one bias electrode.

In various embodiments, the bias DC signal may be pulsed. In this case, a sequence of voltage pulses is applied to at least one bias electrode. The voltage pulse may have a rectangular pulse waveform, a trapezoidal pulse waveform, a triangular pulse waveform, or a combination of these pulse waveforms. In one embodiment, a waveform generator for generating a sequence of voltage pulses from DC signals is connected between the bias DC generator 32a and at least one bias electrode. Accordingly, the bias DC generator 32a and the waveform generator constitute a voltage pulse generator. The voltage pulse may have a positive polarity or a negative polarity. The sequence of voltage pulses may include one or more positive polarity voltage pulses and one or more negative polarity voltage pulses within one cycle. The bias DC generator 32a may be provided in addition to the RF power supply 31 or in place of the second RF generator 31b.

The antenna 14 has an outer coil 141 and an inner coil 142 disposed coaxially with the gas introduction section 16. The inner coil 142 is disposed around the gas introduction section 16 to surround the gas introduction section 16. The outer coil 141 is disposed around the inner coil 142 to surround the inner coil 142. The outer coil 141 serves as a primary coil to which the first RF generator 31a is connected. In one embodiment, the outer coil 141 is a planar coil and is formed in a substantially circular spiral shape. The inner coil 142 serves as a secondary coil inductively coupled to the primary coil. That is, the inner coil 142 is not connected to the first RF generator 31a. In one embodiment, the inner coil 142 is a planar coil and is formed in a substantially circular ring shape. In one embodiment, the inner coil 142 is connected to a variable capacitor, and the direction and magnitude of current flowing through the inner coil 142 is controlled by controlling the capacitance of the variable capacitor. The outer coil 141 and the inner coil 142 may be disposed at the same height or at different heights. In one embodiment, the inner coil 142 is disposed at the same height as the outer coil 141.

The exhaust system 40 can be connected, for example, to a gas discharge port 10e provided at the bottom of the plasma processing chamber 10. The exhaust system 40 may include a pressure regulating valve and a vacuum pump. The pressure in the plasma processing space 10s is regulated by the pressure regulating valve. The vacuum pump may include a turbomolecular pump, a dry pump, or a combination thereof.

The controller 2 processes computer-executable instructions that cause the plasma processing apparatus 1 to perform various processes described in the present disclosure. The controller 2 can be configured to control each element of the plasma processing apparatus 1 to perform the various processes described herein. In one embodiment, some or all of the controller 2 may be included in the plasma processing apparatus 1. The controller 2 may include a processor 2a1, a storage 2a2, and a communication interface 2a3. The controller 2 is implemented by a computer 2a, for example. The processor 2a1 can be configured to perform various control operations by reading computer programs from the storage 2a2 and executing the read computer programs. The computer program may be stored in the storage 2a2 in advance or may be acquired via a medium when needed. The acquired computer program is stored in the storage 2a2 and read from the storage 2a2 by the processor 2a1 for execution. The media may be various storage media readable by the computer 2a or a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### Structure of Antenna 14

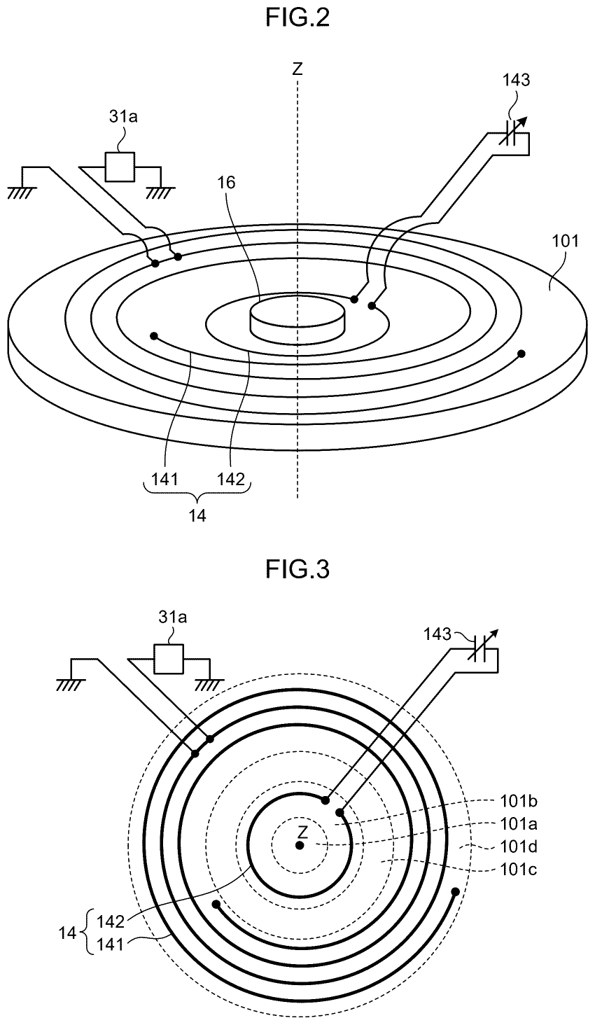

Details of the antenna 14 are described below with reference to FIGS. 2 and 3. FIG. 2 is a schematic perspective view illustrating an example of the antenna in the present embodiment. FIG. 3 is a view illustrating an example of the arrangement of the inner coil and the outer coil in the present embodiment. As illustrated in FIGS. 2 and 3, the antenna 14 is an example of an antenna assembly disposed above the dielectric window 101. In plan view, the antenna 14 is set with a central region 101a, a first surrounding region 101b surrounding the central region 101a, a second surrounding region 101c surrounding the first surrounding region 101b, and a third surrounding region 101d surrounding the second surrounding region 101c. The central region 101a, the first surrounding region 101b, the second surrounding region 101c, and the third surrounding region 101d are set to define the positional relationship between the antenna 14 and the dielectric window 101. In the positional relationship with the dielectric window 101, each gas introduction port 13b is provided at a position that overlaps the second surrounding region 101c in the longitudinal direction.

The outer coil 141 is formed in a substantially circular spiral shape, for example, two or more turns, and is disposed in the third surrounding region 101d so that the central axis of an outer shape of the outer coil 141 coincides with the Z axis. The inner coil 142 is formed in a substantially circular ring shape, for example, and is disposed in the first surrounding region 101b so that the central axis of the inner coil 142 coincides with the Z axis.

The outer coil 141 and the inner coil 142 are planar coils and are disposed above a lower surface of the dielectric window 101, which is a boundary surface with the plasma processing space 10s so that they are substantially parallel to a surface of the substrate W placed on the electrostatic chuck 1111. A distance between the outer coil 141 and the lower surface of the dielectric window 101 is the same as a distance between the inner coil 142 and the lower surface of the dielectric window 101. As another example, the distance between the outer coil 141 and the lower surface of the dielectric window 101 may be different from the distance between the inner coil 142 and the lower surface of the dielectric window 101. A distance between the outer coil 141 and an upper surface of the dielectric window 101 may be longer than a distance between the inner coil 142 and the upper surface of the dielectric window 101. The distance between the outer coil 141 and the lower surface of the dielectric window 101 and the distance between the inner coil 142 and the lower surface of the dielectric window 101 may be configured to be independently changeable by a drive unit (not illustrated).

FIG. 3 illustrates an example of the arrangement of the inner coil 142 and the outer coil 141 when viewed from an orientation along the Z axis. The inner coil 142 is disposed in the first surrounding region 101b so that the center of the circle coincides with the Z-axis.

The outer coil 141 includes a line with two open ends. The first RF generator 31a is connected to the midpoint of a line constituting the outer coil 141 or the vicinity thereof, and source RF power (high frequency power) is supplied to the outer coil 141 from the first RF generator 31a. The vicinity of the midpoint of the line constituting the outer coil 141 is grounded. The outer coil 141 is configured to resonate at λ/2 with respect to a wavelength λ of the source RF power supplied from the first RF generator 31a. That is, the outer coil 141 serves as a planar helical resonator. A voltage generated in the line constituting the outer coil 141 is distributed to be minimum near the midpoint of the line and maximum at both ends of the line. A current generated in the line constituting the outer coil 141 is distributed to be maximum near the midpoint of the line and minimum at both ends of the line. The first RF generator 31a that provides the source RF power to the outer coil 141 can change frequency and power. The frequency and power of the source RF power supplied from the first RF generator 31a to the outer coil 141 are controlled by the controller 2.

The inner coil 142 is connected via a capacitor 143 at both ends of a line constituting the inner coil 142. That is, the inner coil 142 has the line with two ends and the capacitor 143 connected to the two ends. The inner coil 142 is not connected to the first RF generator 31a. The capacitor 143 is a variable capacitance capacitor. The capacitor 143 may be a capacitor with a fixed capacitance. The inner coil 142 is inductively coupled to the outer coil 141, and a current flows through the inner coil 142 in a direction that cancels a magnetic field generated by a current flowing through the outer coil 141. As a result, the source RF power from the first RF generator 31a is indirectly supplied to the inner coil 142. By controlling the capacitance of the capacitor 143, the direction and magnitude of the current flowing through the inner coil 142 with respect to the current flowing through the outer coil 141 can be controlled. The capacitance of the capacitor 143 is controlled by the controller 2.

The current flowing through the outer coil 141 and the current flowing through the inner coil 142 generate concentric magnetic fields around the outer coil 141 and the inner coil 142, and the generated magnetic fields generate induced electric fields along the outer coil 141 and the inner coil 142 in a direction opposite to that of the current flowing through the outer coil 141 and in a direction opposite to that of the current flowing through the inner coil 142. The induced electric field generated in the plasma processing space 10s by the magnetic field transmitted through the dielectric window 101, especially the induced electric field generated directly below the dielectric window 101 accelerates electrons floating in the plasma processing space 10s and causes the accelerated electrons to collide with the processing gas supplied from the plurality of gas channels 13 and the gas channel 15 of the dielectric window 101, thereby turning the processing gas into plasma. Subsequently, ions and active species included in the plasma cause a predetermined process such as etching to be performed on the substrate W on the electrostatic chuck 1111.

### Arrangement of Gas Channels 13 and 15 of Dielectric Window 101

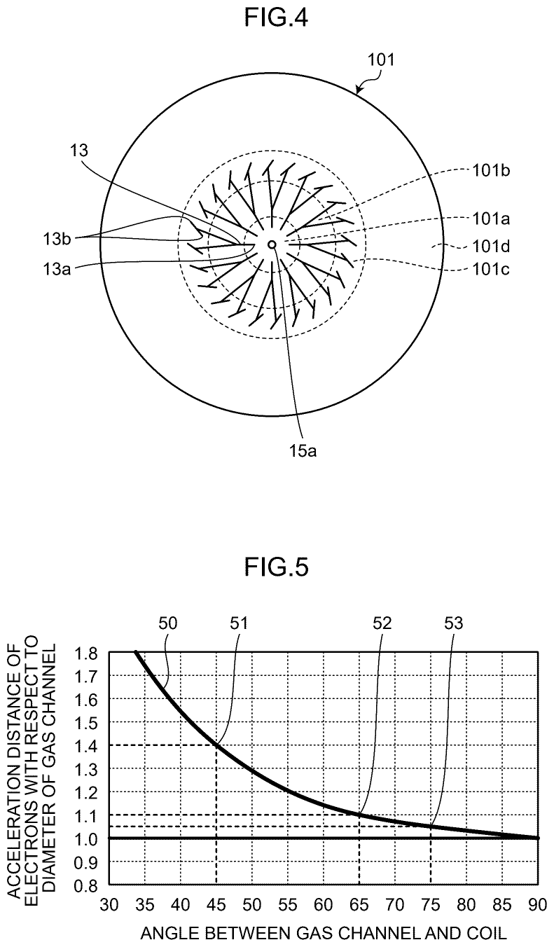

Subsequently, the gas channels 13 and 15 in the dielectric window 101 are described with reference to FIGS. 4 to 6. FIG. 4 is a top view illustrating an example of the dielectric window in the present embodiment. FIG. 4 describes the positional relationship between the gas channels 13 and 15 formed in the dielectric window 101 and the central region 101a, the first surrounding region 101b, the second surrounding region 101c, and the third surrounding region 101d of the antenna 14. In FIG. 4, for description, the gas channels 13 and 15 are represented by solid lines, and the central region 101a, the first surrounding region 101b, the second surrounding region 101c, and the third surrounding region 101d are represented by broken lines. In the following description, for positions that overlap the central region 101a, the first surrounding region 101b, the second surrounding region 101c, and the third surrounding region 101d of the antenna 14 in the longitudinal direction, overlapping in the longitudinal direction may be omitted.

As illustrated in FIG. 4, the gas supply port 15a of the gas channel 15 is disposed at the center of the longitudinally overlapping position of the central region 101a. In addition, each gas supply port 13a of each gas channel 13 is disposed at the longitudinally overlapping position of the central region 101a to surround the gas supply port 15a. At the longitudinally overlapping position of the first surrounding region 101b, each gas channel 13 is extended in the radial direction of the dielectric window 101. In the first surrounding region 101b, each gas channel 13 intersects with the longitudinally overlapping inner coil 142 in plan view. The intersecting herein may include a case where an angle between each gas channel 13 and the longitudinally overlapping inner coil 142 is within a predetermined range including substantial orthogonality with orthogonality as a reference 90°, for example, a range of 90°±45°.

The induced electric field generated by the current flowing through the inner coil 142 also accelerates electrons in each gas channel 13, but when each gas channel 13 and the inner coil 142 are substantially orthogonal in plan view, that is, when the angle between each gas channel 13 and the inner coil 142 is 90°, the electrons can be accelerated only by the distance of a width of each gas channel 13. However, since the electrons collide with the inner walls of each gas channel 13 and disappear, no abnormal discharge occurs. However, when each gas channel 13 and the inner coil 142 are oriented in the same direction in plan view, since the distance over which the electrons can be accelerated is increased, abnormal discharge may occur inside each gas channel 13.

FIG. 5 is a graph illustrating an example of the relationship between the angle between the gas channel and the inner coil and the acceleration distance of electrons. A graph 50 in FIG. 5 illustrates the relationship between the acceleration distance of electrons with respect to the diameter of the gas channel 13 and the angle between each gas channel 13 and the inner coil 142. A point 51 on the graph 50 is a point at which the angle between each gas channel 13 and the inner coil 142 is 45° or 135°. When the angle between each gas channel 13 and the inner coil 142 is 45° to 135°, a movable distance of accelerated electrons is up to about 1.4 times longer than when the angle is 90°, as illustrated in a point 51, which is acceptable for the risk of abnormal discharge. Thus, each gas channel 13 preferably intersects with the inner coil 142 in plan view within the range in which the angle between each gas channel 13 and the inner coil 142 in plan view is 90°±45°.

A point 52 on the graph 50 is a point at which the angle between each gas channel 13 and the inner coil 142 is 65° or 115°. When the angle between each gas channel 13 and the inner coil 142 is 65° to 115°, a movable distance of accelerated electrons is up to about 1.1 times longer than when the angle is 90°, as illustrated in a point 52, which is acceptable for the risk of abnormal discharges. Thus, each gas channel 13 further preferably intersects with the inner coil 142 in plan view within the range in which the angle between each gas channel 13 and the inner coil 142 in plan view is 90°±25°.

Moreover, a point 53 on the graph 50 is a point at which the angle between each gas channel 13 and the inner coil 142 is 75° or 105°. When the angle between each gas channel 13 and the inner coil 142 is 75° to 105°, a movable distance of accelerated electrons is up to about 1.05 times longer than when the angle is 90°, as illustrated in a point 53, which is acceptable for the risk of abnormal discharges. Thus, each gas channel 13 further preferably intersects with the inner coil 142 in plan view within the range in which the angle between each gas channel 13 and the inner coil 142 in plan view is 90°±15°.

In the example in FIG. 4, in the first surrounding region 101b, each gas channel 13 is branched off into two. Each gas introduction port 13b is disposed at the longitudinally overlapping position of the second surrounding region 101c. In the example in FIG. 4, in the second surrounding region 101c, each gas channel 13 is branched off into two. That is, in the example illustrated in FIG. 4, each gas channel 13 has one gas supply port 13a and four gas introduction ports 13b, and the distances from the gas supply port 13a to the gas introduction ports 13b are formed to be equal to each other. In other words, each gas channel 13 is formed to have what is called a tournament structure. Therefore, the conductance can be the same from the gas supply port 13a to each gas introduction port 13b of each gas channel 13, enabling even gas supply. Each gas channel 13 is not formed at the longitudinally overlapping position of the third surrounding region 101d, and the outer coil 141 is disposed in the third surrounding region 101d.

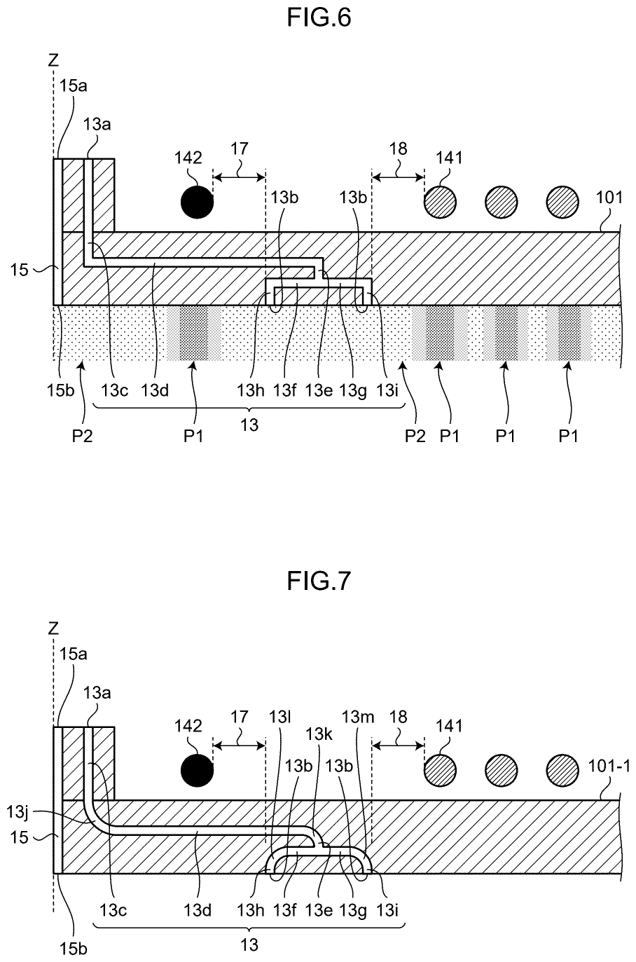

FIG. 6 is a cross-sectional view illustrating an example of the positional relationship between the gas channel and the inner and outer coils. FIG. 6 illustrates a cross-section of one side of the dielectric window 101 in the radial direction from the Z-axis. As illustrated in FIG. 6, the gas channel 13 has, in order from the gas supply port 13a side, a longitudinal channel 13c, a radial (lateral) channel 13d, a longitudinal channel 13e, lateral channels 13f and 13g, and longitudinal channels 13h and 13i.

The channels 13f and 13g are branched off from the channel 13e, and are offset from the radial direction by a predetermined angle. The channel 13f is connected to the channel 13h and the gas introduction port 13b, and the channel 13g is connected to the channel 13i and the gas introduction port 13b. In FIG. 6, the branching in the channel 13d is omitted. The gas channel 15 is a longitudinal channel from the gas supply port 15a to the gas introduction port 15b.

In the plasma processing chamber 10, an induced electric field is generated along the outer coil 141 and the inner coil 142 in the direction opposite to the direction of the current flowing through the outer coil 141 and the direction opposite to the direction of the current flowing through the inner coil 142. That is, in FIG. 6, since the potential of the induced electric field is in the horizontal direction through the paper surface, no abnormal discharge due to the induced electric field occurs inside the lateral channels 13d, 13f, and 13g, and the longitudinal channels 13c, 13e, 13h, and 13i. However, since an induced electric field may be generated from the outer coil 141 and the inner coil 142 and simultaneously an electric field due to capacitive coupling may be generated, the width of each channel is preferably 5 mm or less, for example, in order to prevent abnormal discharge from occurring due to the electric field of the capacitive coupling component.

In the plasma processing chamber 10, plasma is generated by the induced electric field generated in the plasma processing space 10s. In such a case, high-density plasma is generated directly below the dielectric window 101 in terms of the outer coil 141 and the inner coil 142, where the distance between the plasma processing space 10s and the outer coil 141 and the inner coil 142 is the shortest. That is, a high-density plasma generation region P1 and a low-density plasma generation region P2 exist directly below the dielectric window 101. When the gas introduction port 13b is located near the high-density plasma (plasma generation region P1), plasma P1 may enter the channels 13h and 13i from the gas introduction port 13b, resulting in the occurrence of abnormal discharge in the channels 13h and 13i.

In order to prevent this abnormal discharge from occurring, the high-density plasma generation region P1 and the gas introduction port 13b are preferably separated from each other. The distance of the gas introduction port 13b away from the high-density plasma generation region P1 depends on the thickness of the dielectric window 101 and the plasma density. For example, when the dielectric window 101 is about 50 mm thick and the plasma density used for process processing is 5×10¹¹ cm⁻³ or less, the inventor has empirically found that abnormal discharge at the gas introduction port 13b and the channels 13h and 13i can be suppressed by increasing the separation distance to approximately 5 mm or more.

Therefore, the distance between the high-density plasma generation region P1 and the gas introduction port 13b is preferably set to 5 mm or more. That is, the distance between the outer coil 141 or the inner coil 142 and the gas introduction port 13b is preferably set to 5 mm or more. Thus, a radial distance 17 between the gas introduction port 13b and the inner coil 142 is set to, for example, 5 mm or more. A radial distance 18 between the gas introduction port 13b and the outer coil 141 is set to, for example, 5 mm or more. The distances 17 and 18 are each preferably set to 10 mm or more. This can reduce the risk of abnormal discharge in the channels 13h and 13i.

In FIG. 6, the connection part between the longitudinal and lateral channels is L-shaped, but is not limited thereto. FIGS. 7 to 9 are cross-sectional views illustrating an example of the positional relationship between the gas channel and the inner and outer coils. For example, a dielectric window 101-1 illustrated in FIG. 7 is connected to the connection parts of the gas channels 13 by curved channels 13j to 13m. In this way, the connection part of each gas channel 13 may be curved.

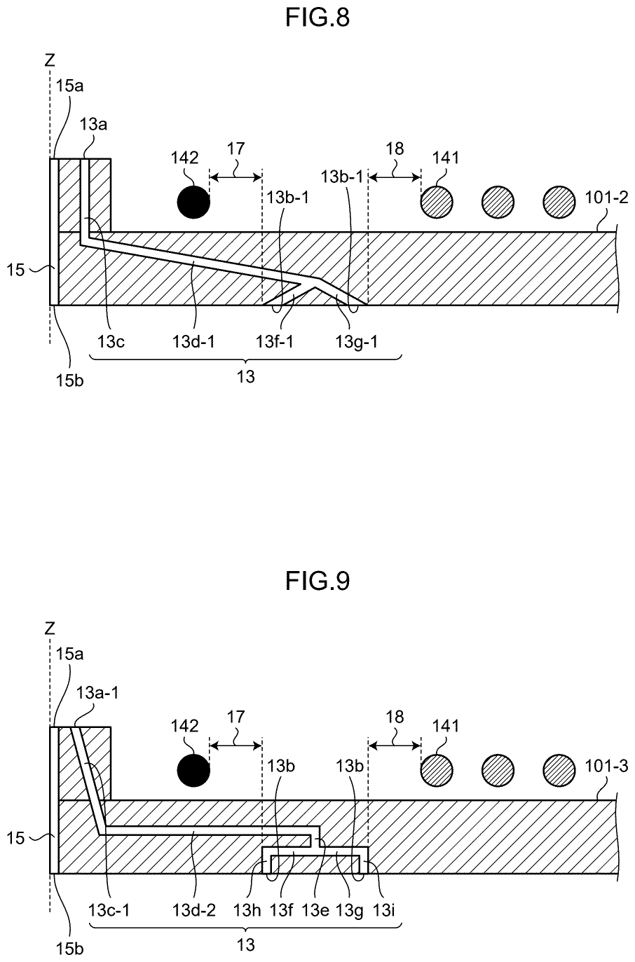

In FIG. 6, the longitudinal channels extend vertically and the lateral channels extend horizontally, but are not limited thereto. For example, a dielectric window 101-2 illustrated in FIG. 8 has channels 13d-1, 13f-1, and 13g-1 inclined with respect to the vertical and horizontal directions. The channels 13f-1 and 13g-1 are connected to gas introduction ports 13b-1, respectively, in the inclined state. For example, in a dielectric window 101-3 illustrated in FIG. 9, a channel 13c-1 is inclined with respect to the vertical direction and connected to a horizontal channel 13d-2. The channel 13c-1 is connected to a gas supply port 13a-1 in the inclined state. In the case of the dielectric windows 101-2 and 101-3, the risk of abnormal discharge due to induced electric fields increases; however, as with the angle between the inner coil 142 and each gas channel 13 in the plan view of FIG. 4, when the inclination with respect to the vertical and horizontal directions is within ±45°, the occurrence of abnormal discharge can be suppressed. A long longitudinal channel (for example, the channel 13c) and a lateral channel (for example, the channel 13d) may be curved.

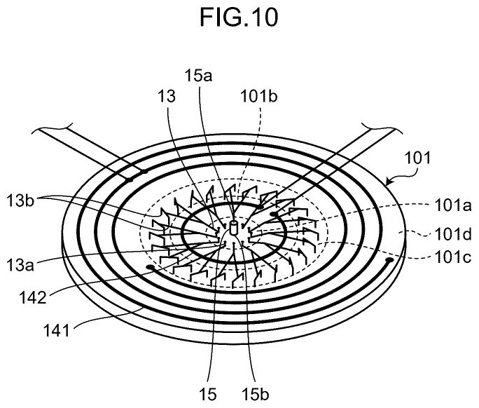

FIG. 10 is a schematic perspective view illustrating an example of the positional relationship between the gas channel and the inner and outer coils. As illustrated in FIG. 10, the gas channel 13 has the gas supply port 13a located in the central region 101a and the gas introduction port 13b located in the second surrounding region 101c. In the first surrounding region 101b where the inner coil 142 is located, since the gas channel 13 is extended in the radial direction and is located to be substantially orthogonal to the inner coil 142, the risk of abnormal discharge is reduced. Since the gas channel 15 has a longitudinal channel from the gas supply port 15a to the gas introduction port 15b located in the central region 101a, the risk of abnormal discharge is reduced. Since the outer coil 141 is located in the third surrounding region 101d, the outer coil 141 is away from the gas introduction port 13b in the radial direction, so that the risk of abnormal discharge is reduced.

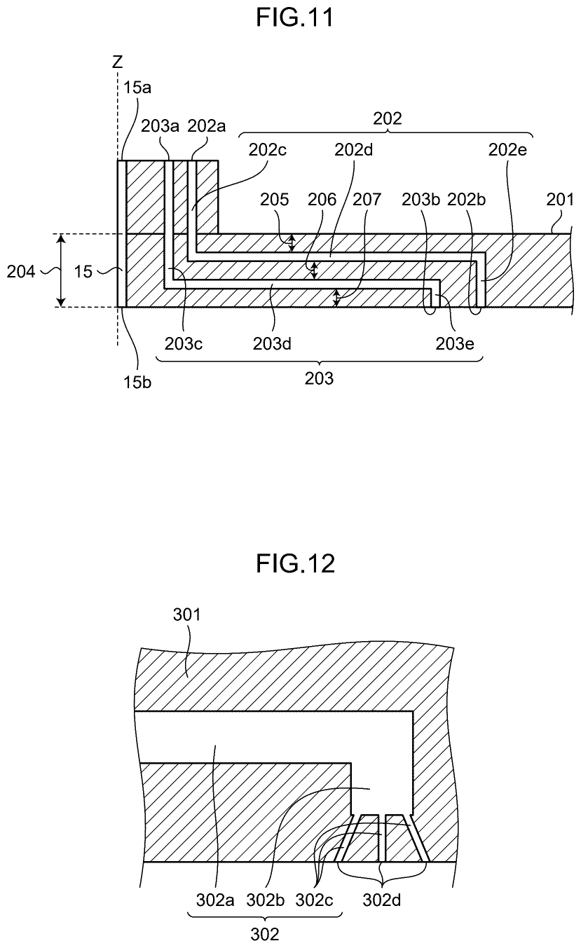

The positional relationship when radial gas channels overlap in the thickness direction of a dielectric window is described below with reference to FIG. 11. FIG. 11 is a cross-sectional view illustrating an example of the positional relationship when the radial gas channels overlap in the thickness direction of the dielectric window. A dielectric window 201 illustrated in FIG. 11 has gas channels 202 and 203 that overlap in the thickness direction of the dielectric window 201, instead of the gas channels 13. The gas channel 202 has a longitudinal channel 202c, a radial channel 202d, and a longitudinal channel 202e, in order from a gas supply port 202a to a gas introduction port 202b. The gas channel 203 has a longitudinal channel 203c, a radial channel 203d, and a longitudinal channel 203e, in order from a gas supply port 203a to a gas introduction port 203b. The gas channels 202 and 203 are examples of gas channels in a radical distribution control (RDC) structure, for example, in which processing gas is divided into two or more systems and the flow is distributed and controlled for each system. In addition, the gas channels 202 and 203 are examples of gas channels in a PostMix structure that reduces the switching time of processing gas by, for example, disposing gas introduction ports alternately for each gas type.

The dielectric window 201 has a thickness 204. The thickness 204 can be set to any thickness in the range of 15 mm to 50 mm, for example. The dielectric window 201 needs to have a mechanical strength to separate the atmosphere from the vacuum. For example, when an ordinary ceramic material is used in a plasma processing apparatus with a substrate W of 300 mm in diameter, the thickness 204 is preferably 15 mm. On the other hand, when the dielectric window is too thick, the distance from the antenna to the inside of the plasma processing chamber 10 becomes too far and an induced electric field in the plasma processing chamber 10 becomes smaller, resulting in lower plasma generation efficiency. Therefore, the thickness 204 is preferably 50 mm or less.

For example, the gas channels 202 and 203 can have a cross-sectional circular shape with any diameter in the range of 2 mm to 5 mm, or a cross-sectional rectangular shape with any length of one side in the range of 2 mm to 5 mm. The cross-sectional size of the gas channels 202 and 203 is preferably at least 2 mm or more in diameter in order to introduce the required flow of processing gas into the plasma processing space 10s. On the other hand, when the cross section is too large, the mechanical strength of the dielectric window may be weakened and the dielectric window may be damaged, and abnormal discharge due to capacitive coupling components may occur inside the gas channels 202 and 203; therefore, the diameter or one side of each of the gas channels 202 and 203 is preferably 5 mm or less.

In addition, when a spacing between the internal gas channels 202 and 203 is unbalanced, the dielectric window 201 is vulnerable to bending stress and may crack. Therefore, a thickness 205 from an upper surface of the dielectric window 201 to the channel 202d, a thickness 206 from the channel 202d to the channel 203d, and a thickness 207 from the channel 203d to a lower surface of the dielectric window 201 are preferably equally spaced. Moreover, the thicknesses 205 to 207 are each preferably 3 mm or more, for example, in order to ensure strength. When the dielectric window 201 has one line of gas channels 13 in the thickness direction as in the above-described dielectric window 101, the thickness from the upper and lower surfaces of the dielectric window 101 to the channel 13d is preferably 3 mm or more. Moreover, the channel 13d is preferably disposed at the center of the dielectric window 101 in the longitudinal (thickness) direction. This thickness between the radial gas channels can suppress cracking of the dielectric windows 101 and 201.

### Channel Near Gas Introduction Port

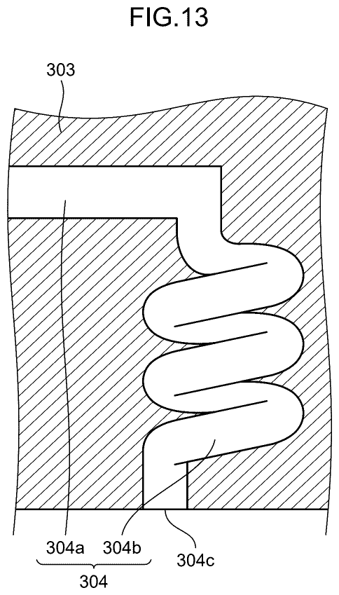

Subsequently, channels near a gas introduction port are described with reference to FIGS. 12 to 14. In the channels 13h and 13i connected to the gas introduction port 13b illustrated in FIG. 6 above, they are represented as having substantially the same thickness as the upstream channels 13c to 13g, but they may be made more complex in order to further suppress abnormal discharge. The dielectric windows 101, 201, and 301, and dielectric windows 303 and 305 according to the present embodiment are formed as an integral structure by a mold casting method without joining a plurality of components. This allows complex channel formation at low cost.

FIGS. 12 to 14 are cross-sectional views illustrating an example of a channel near a gas introduction port. The dielectric window 301 illustrated in FIG. 12 has a radial channel 302a, a longitudinal channel 302b, and a plurality of channels 302c thinner than the channel 302b as a gas channel 302, and gas introduction ports 302d corresponding to respective channels 302c, in order from the gas supply port side. FIG. 12 does not illustrate the gas channel 302 on the gas supply port side. Each channel 302c is a longitudinal or oblique shower structure channel. Each gas introduction port 302d may also be an extent including each channel 302c. Each channel 302c has a narrower internal space and more oblique channels, so that abnormal discharge can be further suppressed. Each channel 302c may be used to control the flow of processing gas by adjusting the number and diameter of the channels.

The dielectric window 303 illustrated in FIG. 13 has a radial channel 304a and a longitudinal channel 304b as a gas channel 304, and a gas introduction port 304c corresponding to the channel 304b, in order from the gas supply port side. FIG. 13 does not illustrate the gas channel 304 on the gas supply port side. Since the channel 304b is spiral-shaped, a space continuous in the longitudinal direction is narrow, so that abnormal discharge can be further suppressed. The gas introduction port 304c may also be an extent including the channel 304b.

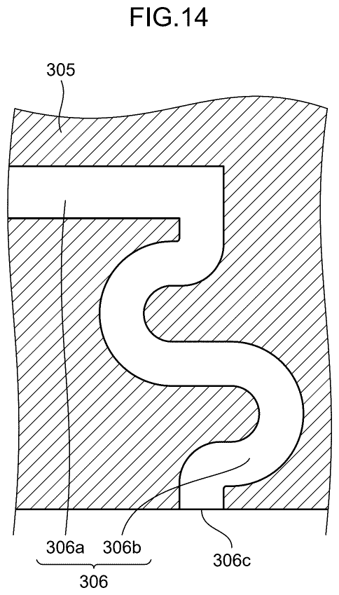

The dielectric window 305 illustrated in FIG. 14 has a radial channel 306a and a longitudinal channel 306b as a gas channel 306, and a gas introduction port 306c corresponding to the channel 306b, in order from the gas supply port side. FIG. 14 does not illustrate the gas channel 306 on the gas supply port side. Since the channel 306b is labyrinth-shaped, a space continuous in the longitudinal direction is narrow, so that abnormal discharge can be further suppressed. The gas introduction port 306c may also be an extent including the channel 306b. In addition, in the mold casting method, the spiral shape or labyrinth shape can be formed by vaporizing a mold made of resin or the like during firing.

In the dielectric windows 101, 201, 301, 303, and 305 according to the present embodiment, a Faraday shield may be formed by metal embedding, metal film, or the like, or a refrigerant channel for cooling, a heater, or the like may be embedded by the mold casting method. Moreover, alignment is required when a dielectric window is formed by a structure of laminating a plurality of components; however, the dielectric window 101 and the like are formed by integral molding in the present embodiment, thereby reducing machine differences.

In the embodiment described above, a spiral coil with an open end is used as the antenna 14; however, the present disclosure is not limited thereto. For example, the antenna may be a coil with an RF generator connected to one end of a line and grounded at the other end, a loop-shaped coil, or a coil having any other shape.

In the embodiment described above, the antenna 14 has the inner coil 142 and the outer coil 141, the outer coil 141 is connected to the first RF generator 31a, and the inner coil 142 is inductively coupled to the outer coil 141; however, the present disclosure is not limited thereto. For example, the first RF generator 31a may be connected to the inner coil 142 and the outer coil 141 may be inductively coupled to the inner coil 142, or the first RF generator 31a may be connected to the inner coil 142 and the outer coil 141 independently. The inner coil 142 and/or the outer coil 141 may be inductively coupled to a coil installed above the inner coil 142 and/or the outer coil 141 and to which the first RF generator 31a is connected, so that source RF power may be supplied.

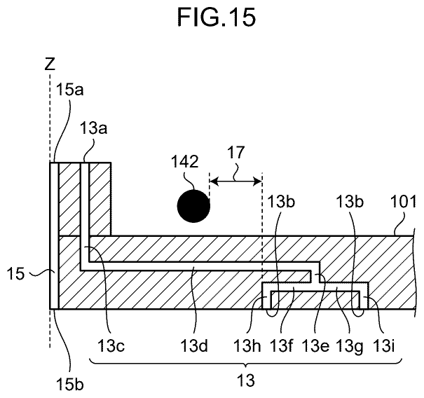

In the embodiment described above, the antenna 14 has two coils, the inner coil 142 and the outer coil 141, and is set with the central region 101a, the first surrounding region 101b surrounding the central region 101a, the second surrounding region 101c surrounding the first surrounding region 101b, and the third surrounding region 101d surrounding the second surrounding region 101c, and the inner coil 142 is disposed in the first surrounding region 101b and the outer coil 141 is disposed in the third surrounding region 101d; however, the present disclosure is not limited thereto. FIG. 15 is a cross-sectional view illustrating an example of the positional relationship between the gas channel and the inner coil. As illustrated in FIG. 15, for example, the antenna 14 may have only one inner coil 142. Each of the gas introduction ports 13b is provided at a position that overlaps the second surrounding region 101c in the longitudinal direction.

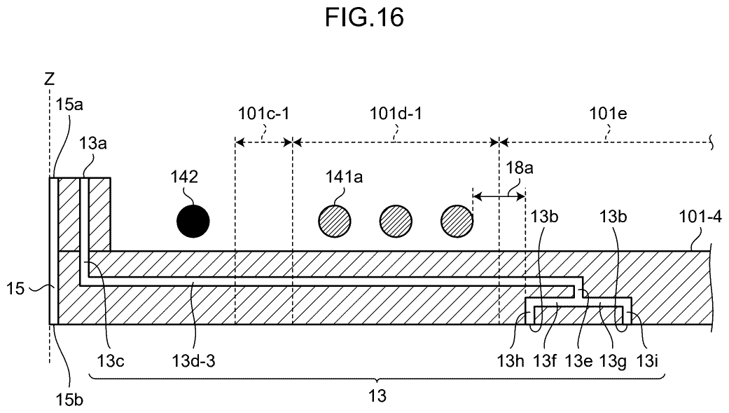

In the embodiment described above, each of the gas introduction ports 13b is provided at a position that overlaps the second surrounding region 101c in the longitudinal direction; however, the present disclosure is not limited thereto. Variations in the arrangement of each gas channel 13 and the outer coil 141 and the inner coil 142 are described below with reference to FIGS. 16 to 20. FIG. 16 is a cross-sectional view illustrating an example of the positional relationship between the gas channel and the inner and outer coils. As in a dielectric window 101-4 illustrated in FIG. 16, for example, a fourth surrounding region 101e is further set to surround a third surrounding region 101d-1, and each of the plurality of gas channels 13 may be extended to the fourth surrounding region 101e in the radial direction of the dielectric window 101-4. For example, each of the plurality of gas channels 13 is extended as illustrated in a channel 13d-3. Each of the gas introduction ports 13b may be moved from a second surrounding region 101c-1 and provided at a position that overlaps the fourth surrounding region 101e in the longitudinal direction. Each of the gas introduction ports 13b is provided at a position away from an outer coil 141a by 5 mm or more as illustrated as a distance 18a.

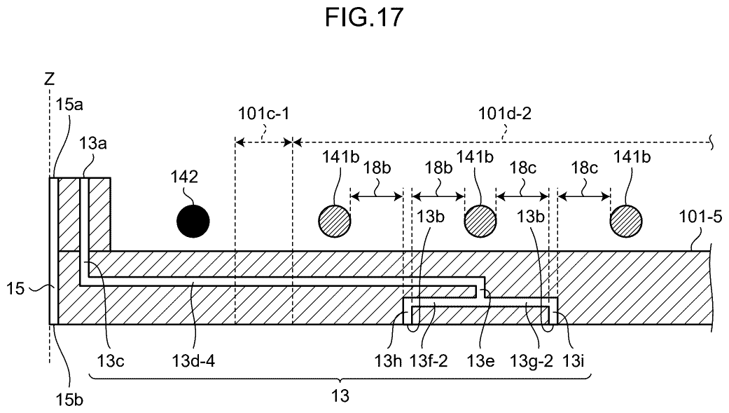

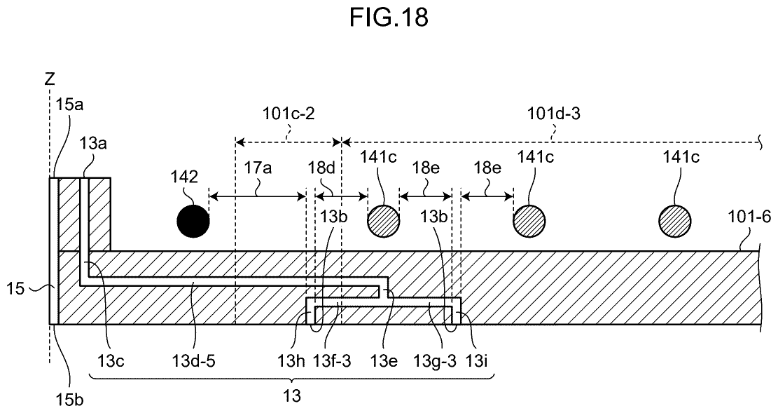

FIGS. 17 and 18 are cross-sectional views illustrating an example of the positional relationship between the gas channel and the inner and outer coils. As in a dielectric window 101-5 illustrated in FIG. 17, for example, each of the gas introduction ports 13b may be provided at a position that overlaps a third surrounding region 101d-2, where an outer coil 141b is disposed, in the longitudinal direction. When the outer coil 141b is formed in a substantially circular spiral shape, for example, two or more turns and an interval between the turns is 10 mm or more, the risk of abnormal discharge can be reduced by positioning each of the gas introduction ports 13b in the middle of the interval between turns. In this case, each gas channel 13 is extended, for example, like channels 13d-4, 13f-2, and 13g-2. The interval between the turns of the outer coil 141b is set so that radial distances 18b and 18c between the gas introduction port 13b and the outer coil 141b are 5 mm or more, for example. That is, each of the gas introduction ports 13b may be provided at a position that overlaps any one of the second surrounding region 101c-1 and the third surrounding region 101d-2 in the longitudinal direction. As in a dielectric window 101-6 illustrated in FIG. 18, each of the gas introduction ports 13b may be provided at a position that overlaps both a second surrounding region 101c-2 and a third surrounding region 101d-3 in the longitudinal direction. In this case, each gas channel 13 is extended, for example, like channels 13d-5, 13f-3, and 13g-3. The interval between the turns of the outer coil 141b is set so that radial distances 18d and 18e between the gas introduction port 13b and an outer coil 141c are 5 mm or more, for example. Moreover, a radial distance 17a between the gas introduction port 13b and the inner coil 142 is disposed to be 5 mm or more, for example. In other words, each of the gas introduction ports 13b is provided at a position away from the outer coils 141b and 141c by 5 mm or more.

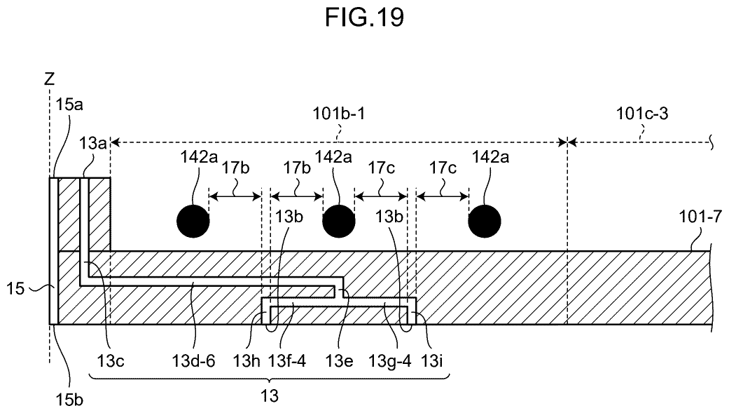

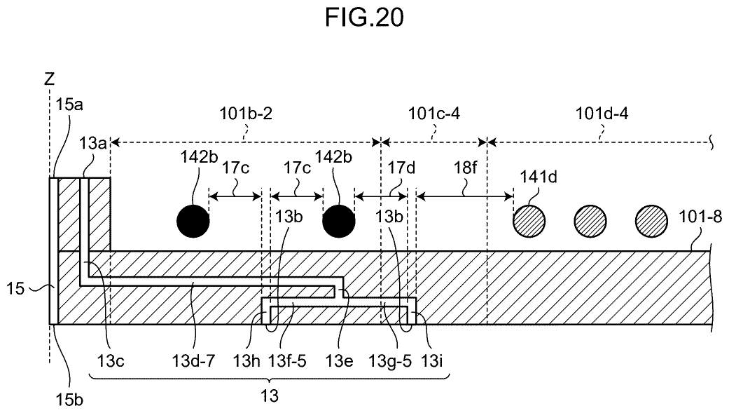

FIG. 19 is a cross-sectional view illustrating an example of the positional relationship between the gas channel and the inner coil. FIG. 20 is a cross-sectional view illustrating an example of the positional relationship between the gas channel and the inner and outer coils. As in a dielectric window 101-7 illustrated in FIG. 19, for example, each of the gas introduction ports 13b may be provided at a position that overlaps a first surrounding region 101b-1, where an inner coil 142a is disposed, in the longitudinal direction. When the inner coil 142a is formed in in a substantially circular spiral shape, for example, two or more turns and an interval between the turns is 10 mm or more, the risk of abnormal discharge can be reduced by positioning each of the gas introduction ports 13b in the middle of the interval between turns. In this case, each gas channel 13 is extended, for example, like channels 13d-6, 13f-4, and 13g-4. The interval between the turns of the inner coil 142a is set so that radial distances 17b and 17c between the gas introduction port 13b and the inner coil 142a are 5 mm or more, for example. That is, each of the gas introduction ports 13b may be provided at a position that overlaps any one of the first surrounding region 101b-1 and a second surrounding region 101c-3 in the longitudinal direction. As in a dielectric window 101-8 illustrated in FIG. 20, each of the gas introduction ports 13b may be provided at a position that overlaps at least one of a first surrounding region 101b-2 and a second surrounding region 101c-4 in the longitudinal direction. In this case, each gas channel 13 is extended, for example, like channels 13d-7, 13f-5, and 13g-5. The interval between the turns of an inner coil 142b is set so that radial distances 17c and 17d between the gas introduction port 13b and the inner coil 142b are 5 mm or more, for example. Moreover, a radial distance 18f between the gas introduction port 13b and an outer coil 141d in a third surrounding region 101d-4 is disposed to be 5 mm or more, for example. In other words, each of the gas introduction ports 13b is provided at a position away from the inner coils 142a and 142b by 5 mm or more.

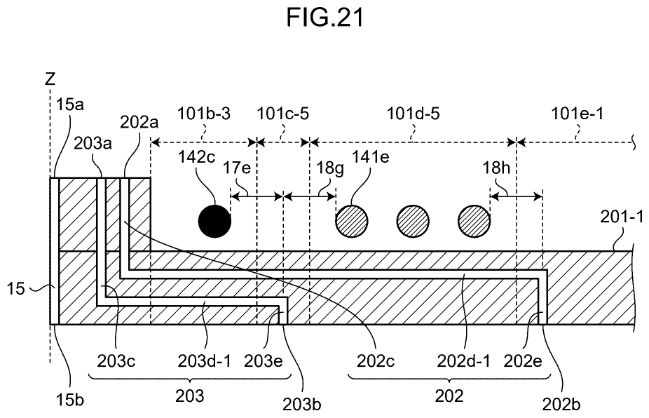

In the embodiment described above, in the dielectric window 201, each gas introduction port 202b is provided at a position that overlaps the second surrounding region 101c in the longitudinal direction, as with the gas introduction port 13b of the dielectric window 101; however, the present disclosure is not limited thereto. FIG. 21 is a cross-sectional view illustrating an example of the positional relationship between the gas channel and the inner and outer coils. As in a dielectric window 201-1 illustrated in FIG. 21, for example, a fourth surrounding region 101e-1 may further be set to surround a third surrounding region 101d-5, and at least one of the plurality of gas channels 202 and 203 may be extended to the fourth surrounding region 101e-1 in the radial direction of the dielectric window 201-1. For example, at least one of the plurality of gas channels 13 is extended as illustrated in a channel 202d-1. In the example of the dielectric window 201-1, since the gas introduction port 203b is disposed in a second surrounding region 101c-5, a channel 203d-1 is extended to the second surrounding region 101c-5. At least one of the gas introduction ports 202b and 203b may be moved from the second surrounding region 101c-5 and provided at a position that overlaps the fourth surrounding region 101e-1 in the longitudinal direction. The gas introduction ports 202b and 203b are provided at positions away from an outer coil 141e by 5 mm or more as illustrated at distances 18g and 18h. The gas introduction port 203b is provided at a position away from an inner coil 142c, which is provided at a position that overlaps a first surrounding region 101b-3 in the longitudinal direction, by 5 mm or more as illustrated as a distance 17e.

According to the present embodiment above, the plasma processing apparatus 1 includes a chamber (plasma processing chamber 10), the gas supply section 20, an antenna assembly (antenna 14), and an RF power supply (first RF generator 31a). The chamber accommodates the substrate W and includes the dielectric window 101 constituting the upper part of the chamber and formed therein with the plurality of gas channels 13. The gas supply section 20 is connected to the plurality of gas channels 13 and configured to supply processing gas into the chamber. The antenna assembly is disposed above the chamber and is set with the central region 101a, the first surrounding region 101b surrounding the central region 101a, the second surrounding region 101c surrounding the first surrounding region 101b, and the third surrounding region 101d surrounding the second surrounding region 101c, and includes the primary coil (outer coil 141) disposed in the third surrounding region 101d and the secondary coil (inner coil 142) disposed in the first surrounding region 101b. The RF power supply is configured to supply RF power to at least one of the primary coil and the secondary coil. Each of the plurality of gas channels 13 extends in the radial direction of the dielectric window 101 and is formed so that distances from the gas supply port 13a connected to the gas supply section 20 to the gas introduction ports 13b for introducing the processing gas into the chamber are equal to each other. As a result, the processing gas can be evenly supplied while suppressing abnormal discharge.

According to the present embodiment, each of the gas introduction ports 13b is provided at a position that overlaps the second surrounding region 101c in the longitudinal direction. As a result, the processing gas can be evenly supplied while suppressing abnormal discharge.

According to the present embodiment, the primary coil is formed in a substantially circular spiral shape, and each of the gas introduction ports 13b is provided at a position that overlaps any one of the second surrounding region 101c and the third surrounding region 101d in the longitudinal direction. As a result, the processing gas can be evenly supplied while suppressing abnormal discharge.

According to the present embodiment, each of the gas supply ports 13a is provided in a position that overlaps the central region 101a in the longitudinal direction. As a result, the processing gas can be evenly supplied while suppressing abnormal discharge.

According to the present embodiment, each of the plurality of gas channels 13 is orthogonal to the secondary coil in plan view, or intersects with the secondary coil in plan view in a range in which an angle between each of the plurality of gas channels 13 and the secondary coil in plan view is 90°±45°. As a result, abnormal discharge directly below the secondary coil can be suppressed.

According to the present embodiment, each of the plurality of gas channels 13 is formed so that a tournament structure is formed from the one gas supply port 13a to the plurality of the gas introduction ports 13b. As a result, the processing gas can be evenly supplied to the plurality of gas introduction ports 13b.

According to the present embodiment, the gas introduction port 13b is provided at a position away from the primary coil and the secondary coil by 5 mm or more. As a result, abnormal discharge can be suppressed.

According to the present embodiment, the gas introduction port 13b is formed to have a spiral or labyrinth structure. As a result, abnormal discharge near the gas introduction port 13b can be suppressed.

According to the present embodiment, the gas channels 202 and 203 are disposed at positions where the dielectric window 201 in portions (channels 202d and 203d) extending in the radial direction is even with respect to a longitudinal thickness (thickness 204). As a result, cracking of the dielectric window 201 can be suppressed.

According to the present embodiment, the dielectric window 101 is formed therein with the gas channel 15 with the gas supply port 15a and the gas introduction port 15b at a position that overlaps the central region 101a in the longitudinal direction. As a result, the in-plane uniformity of the processing gas can be further controlled.

According to the present embodiment, the antenna assembly is further set with the fourth surrounding region 101e surrounding the third surrounding region 101d-1. Each of the plurality of gas channels 13 is extended to the fourth surrounding region 101e in the radial direction of the dielectric window 101-4. Each of the gas introduction ports 13b is provided at a position that overlaps the fourth surrounding region 101e in the longitudinal direction. As a result, the in-plane uniformity of the processing gas can be further improved.

According to the present embodiment, the plasma processing apparatus 1 includes a chamber (plasma processing chamber 10), the gas supply section 20, an antenna assembly (antenna 14), and an RF power supply (first RF generator 31a). The chamber accommodates the substrate W and includes the dielectric window 101 constituting the upper part of the chamber and formed therein with the plurality of gas channels 13. The gas supply section 20 is connected to the plurality of gas channels 13 and configured to supply processing gas into the chamber. The antenna assembly is disposed above the chamber and is set with the central region 101a, the first surrounding region 101b surrounding the central region 101a, and the second surrounding region 101c surrounding the first surrounding region 101b, and includes a coil (inner coil 142) disposed in the first surrounding region 101b. The RF power supply is configured to supply RF power to the coil. Each of the plurality of gas channels 13 extends in the radial direction of the dielectric window 101 and is formed so that distances from the gas supply port 13a connected to the gas supply section 20 to the gas introduction ports 13b for introducing the processing gas into the chamber are equal to each other. As a result, the processing gas can be evenly supplied while suppressing abnormal discharge.

According to the present embodiment, a coil (inner coil 142a) is formed in a substantially circular spiral shape, and each of the gas introduction ports 13b is provided at a position that overlaps the first surrounding region 101b-1 in the longitudinal direction. As a result, the processing gas can be evenly supplied while suppressing abnormal discharge.

According to the present embodiment, a coil (inner coil 142b) is formed in a substantial circular spiral shape, and each of the gas introduction ports 13b is provided at a position that overlaps at least one of the first surrounding region 101b-2 and the second surrounding region 101c-4 in the longitudinal direction. As a result, the processing gas can be evenly supplied while suppressing abnormal discharge.

The embodiments disclosed herein should be considered exemplary in all respects and not restrictive. The above embodiments may be omitted, replaced, or modified in various forms without departing from the scope of the appended claims and the subject matter thereof.

Note that the above embodiments are not limited to etching, but can also be applied to an apparatus for film deposition, modification, and other processes, as long as the apparatus uses an ICP-type plasma source to treat a substrate.

Note that the present disclosure can also be configured as follows.

(1)

A plasma processing apparatus including:
a chamber configured to accommodate a substrate and including a dielectric window constituting an upper part of the chamber and formed therein with a plurality of gas channels;
a gas supply section connected to the plurality of gas channels and configured to supply processing gas into the chamber;
an antenna assembly that is disposed above the chamber, is set with a central region, a first surrounding region surrounding the central region, a second surrounding region surrounding the first surrounding region, and a third surrounding region surrounding the second surrounding region, and includes a primary coil disposed in the third surrounding region and a secondary coil disposed in the first surrounding region; and
a radio frequency (RF) power supply configured to supply RF power to at least one of the primary coil and the secondary coil,
wherein each of the plurality of gas channels extends in a radial direction of the dielectric window and is formed so that distances from a gas supply port connected to the gas supply section to gas introduction ports for introducing the processing gas into the chamber are equal to each other.
   (2)

The plasma processing apparatus according to (1), wherein each of the gas introduction ports is provided at a position that overlaps the second surrounding region in a longitudinal direction.

(3)

The plasma processing apparatus according to (1), wherein
the primary coil is formed in a substantially circular spiral shape, and
each of the gas introduction ports is provided at a position that overlaps any one of the second surrounding region and the third surrounding region in a longitudinal direction.
   (4)

The plasma processing apparatus according to (1), wherein each of the gas supply ports is provided at a position that overlaps the central region in a longitudinal direction.

(5)

The plasma processing apparatus according to any one of (1) to (4), wherein each of the plurality of gas channels is orthogonal to the secondary coil in plan view, or intersects with the secondary coil in plan view in a range in which an angle between each of the plurality of gas channels and the secondary coil in plan view is 90° +45°.

(6)

The plasma processing apparatus according to any one of (1) to (5), wherein each of the plurality of gas channels is formed so that a tournament structure is formed from the one gas supply port to a plurality of the gas introduction ports.

(7)

The plasma processing apparatus according to any one of (1) to (6), wherein the gas introduction port is provided at a position away from the primary coil and the secondary coil by 5 mm or more.

(8)

The plasma processing apparatus according to any one of (1) to (7), wherein the gas introduction port is formed to have a spiral or labyrinth structure.

(9)

The plasma processing apparatus according to any one of (1) to (8), wherein the gas channels are disposed at positions where the dielectric window in portions extending in the radial direction is even with respect to a longitudinal thickness.

(10)

The plasma processing apparatus according to any one of (1) to (9), wherein the dielectric window is formed therein with a gas channel with the gas supply port and the gas introduction port at a position that overlaps the central region in a longitudinal direction.

(11)

The plasma processing apparatus according to (1), wherein
the antenna assembly is further set with a fourth surrounding region surrounding the third surrounding region, and
each of the plurality of gas channels is extended to the fourth surrounding region in the radial direction of the dielectric window, and
each of the gas introduction ports is provided at a position that overlaps the fourth surrounding region in a longitudinal direction.
   (12)

A dielectric window constituting an upper part of a chamber of a plasma processing apparatus, the dielectric window including:
a plurality of gas channels extending in a radial direction of the dielectric window and each formed so that distances from a gas supply port connected to a gas supply section to gas introduction ports for introducing processing gas into the chamber are equal to each other, the gas supply section supplying the processing gas to the chamber,
wherein each of the gas introduction ports is provided at a position that overlaps a second surrounding region in a longitudinal direction with respect to an antenna assembly that is disposed above the chamber, is set with a central region, a first surrounding region surrounding the central region, the second surrounding region surrounding the first surrounding region, and a third surrounding region surrounding the second surrounding region, and includes a primary coil disposed in the third surrounding region and a secondary coil disposed in the first surrounding region.
   (13)

A plasma processing apparatus including:
a chamber configured to accommodate a substrate and including a dielectric window constituting an upper part of the chamber and formed therein with a plurality of gas channels;
a gas supply section connected to the plurality of gas channels and configured to supply processing gas to the chamber;
an antenna assembly that is disposed above the chamber, is set with a central region, a first surrounding region surrounding the central region, and a second surrounding region surrounding the first surrounding region, and includes a coil disposed in the first surrounding region; and
a radio frequency (RF) power supply configured to supply RF power to the coil,
wherein each of the plurality of gas channels extends in a radial direction of the dielectric window and is formed so that distances from a gas supply port connected to the gas supply section to gas introduction ports for introducing the processing gas into the chamber are equal to each other.
   (14)

The plasma processing apparatus according to (13), wherein each of the gas introduction ports is provided at a position that overlaps the second surrounding region in a longitudinal direction.

(15)

The plasma processing apparatus according to (13), wherein
the coil is formed in a substantially circular spiral shape, and
each of the gas introduction ports is provided at a position that overlaps the first surrounding region in a longitudinal direction.
   (16)

The plasma processing apparatus according to (13), wherein
the coil is formed in a substantially circular spiral shape, and
each of the gas introduction ports is provided at a position that overlaps at least one of the first surrounding region and the second surrounding region in a longitudinal direction.
   (17)

The plasma processing apparatus according to (13), wherein each of the gas supply ports is provided at a position that overlaps the central region in a longitudinal direction.

(18)

The plasma processing apparatus according to any one of (13) to (17), wherein each of the plurality of gas channels is orthogonal to the coil in plan view, or intersects with the coil in plan view in a range in which an angle between each of the plurality of gas channels and the coil in plan view is 90°±45°.

(19)

The plasma processing apparatus according to any one of (13) to (18), wherein each of the plurality of gas channels is formed so that a tournament structure is formed from the one gas supply port to a plurality of the gas introduction ports.

(20)

The plasma processing apparatus according to any one of (13) to (19), wherein the gas introduction port is provided at a position away from the coil by 5 mm or more.

(21)

The plasma processing apparatus according to any one of (13) to (20), wherein the gas introduction port is formed to have a spiral or labyrinth structure.

(22)

The plasma processing apparatus according to any one of (13) to (21), wherein the gas channels are disposed in a plural number in a longitudinal direction of the dielectric window, and are disposed at positions where the dielectric window in portions extending in the radial direction is even with respect to a longitudinal thickness.

(23)

The plasma processing apparatus according to any one of (13) to (22), wherein the dielectric window is formed therein with a gas channel with the gas supply port and the gas introduction port at a position that overlaps the central region in a longitudinal direction.

(24)

A dielectric window constituting an upper part of a chamber of a plasma processing apparatus, the dielectric window including:
a plurality of gas channels extending in a radial direction of the dielectric window and each formed so that distances from a gas supply port connected to a gas supply section to gas introduction ports for introducing processing gas into the chamber are equal to each other, the gas supply section supplying the processing gas to the chamber,
wherein each of the gas introduction ports is provided at a position that overlaps a second surrounding region in a longitudinal direction with respect to an antenna assembly that is disposed above the chamber, is set with a central region, a first surrounding region surrounding the central region, and the second surrounding region surrounding the first surrounding region, and includes a coil disposed in the first surrounding region.

The present disclosure can evenly supply processing gas while suppressing abnormal discharge.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A plasma processing apparatus comprising:
a chamber configured to accommodate a substrate and including a dielectric window constituting an upper part of the chamber and formed therein with a plurality of gas channels;
a gas supply section connected to the plurality of gas channels and configured to supply processing gas into the chamber;
an antenna assembly that is disposed above the chamber, is set with a central region, a first surrounding region surrounding the central region, a second surrounding region surrounding the first surrounding region, and a third surrounding region surrounding the second surrounding region, and includes a primary coil disposed in the third surrounding region and a secondary coil disposed in the first surrounding region; and
a radio frequency (RF) power supply configured to supply RF power to at least one of the primary coil and the secondary coil,
wherein each of the plurality of gas channels extends in a radial direction of the dielectric window and is formed so that distances from a gas supply port connected to the gas supply section to gas introduction ports for introducing the processing gas into the chamber are equal to each other.

2. The plasma processing apparatus according to claim 1, wherein each of the gas introduction ports is provided at a position that overlaps the second surrounding region in a longitudinal direction.

3. The plasma processing apparatus according to claim 1, wherein
the primary coil is formed in a substantially circular spiral shape, and
each of the gas introduction ports is provided at a position that overlaps any one of the second surrounding region and the third surrounding region in a longitudinal direction.

4. The plasma processing apparatus according to claim 1, wherein each of the gas supply ports is provided at a position that overlaps the central region in a longitudinal direction.

5. The plasma processing apparatus according to claim 1, wherein each of the plurality of gas channels is orthogonal to the secondary coil in plan view, or intersects with the secondary coil in plan view in a range in which an angle between each of the plurality of gas channels and the secondary coil in plan view is 90°±45°.

6. The plasma processing apparatus according to claim 1, wherein each of the plurality of gas channels is formed so that a tournament structure is formed from the one gas supply port to a plurality of the gas introduction ports.

7. The plasma processing apparatus according to claim 1, wherein the gas introduction port is provided at a position away from the primary coil and the secondary coil by 5 mm or more.

8. The plasma processing apparatus according to claim 1, wherein the gas introduction port is formed to have a spiral or labyrinth structure.

9. The plasma processing apparatus according to claim 1, wherein the gas channels are disposed at positions where the dielectric window in portions extending in the radial direction is even with respect to a longitudinal thickness.

10. The plasma processing apparatus according to claim 1, wherein the dielectric window is formed therein with a gas channel with the gas supply port and the gas introduction port at a position that overlaps the central region in a longitudinal direction.

11. The plasma processing apparatus according to claim 1, wherein
the antenna assembly is further set with a fourth surrounding region surrounding the third surrounding region, and
each of the plurality of gas channels is extended to the fourth surrounding region in the radial direction of the dielectric window, and
each of the gas introduction ports is provided at a position that overlaps the fourth surrounding region in a longitudinal direction.

12. A dielectric window constituting an upper part of a chamber of a plasma processing apparatus, the dielectric window comprising:
a plurality of gas channels extending in a radial direction of the dielectric window and each formed so that distances from a gas supply port connected to a gas supply section to gas introduction ports for introducing processing gas into the chamber are equal to each other, the gas supply section supplying the processing gas to the chamber,
wherein each of the gas introduction ports is provided at a position that overlaps a second surrounding region in a longitudinal direction with respect to an antenna assembly that is disposed above the chamber, is set with a central region, a first surrounding region surrounding the central region, the second surrounding region surrounding the first surrounding region, and a third surrounding region surrounding the second surrounding region, and includes a primary coil disposed in the third surround region and a secondary coil disposed in the first surrounding region.

13. A plasma processing apparatus comprising:
a chamber configured to accommodate a substrate and including a dielectric window constituting an upper part of the chamber and formed therein with a plurality of gas channels;
a gas supply section connected to the plurality of gas channels and configured to supply processing gas to the chamber;
an antenna assembly that is disposed above the chamber, is set with a central region, a first surrounding region surrounding the central region, and a second surrounding region surrounding the first surrounding region, and includes a coil disposed in the first surrounding region; and
a radio frequency (RF) power supply configured to supply RF power to the coil,
wherein each of the plurality of gas channels extends in a radial direction of the dielectric window and is formed so that distances from a gas supply port connected to the gas supply section to gas introduction ports for introducing the processing gas into the chamber are equal to each other.

14. The plasma processing apparatus according to claim 13, wherein each of the gas introduction ports is provided at a position that overlaps the second surrounding region in a longitudinal direction.

15. The plasma processing apparatus according to claim 13, wherein
the coil is formed in a substantially circular spiral shape, and
each of the gas introduction ports is provided at a position that overlaps the first surrounding region in a longitudinal direction.

16. The plasma processing apparatus according to claim 13, wherein
the coil is formed in a substantially circular spiral shape, and
each of the gas introduction ports is provided at a position that overlaps at least one of the first surrounding region and the second surrounding region in a longitudinal direction.

17. The plasma processing apparatus according to claim 13, wherein each of the gas supply ports is provided at a position that overlaps the central region in a longitudinal direction.

18. The plasma processing apparatus according to claim 13, wherein each of the plurality of gas channels is orthogonal to the coil in plan view, or intersects with the coil in plan view in a range in which an angle between each of the plurality of gas channels and the coil in plan view is 90°±45°.

19. The plasma processing apparatus according to claim 13, wherein each of the plurality of gas channels is formed so that a tournament structure is formed from the one gas supply port to a plurality of the gas introduction ports.

20. The plasma processing apparatus according to claim 13, wherein the gas introduction port is provided at a position away from the coil by 5 mm or more.

21. The plasma processing apparatus according to claim 13, wherein the gas introduction port is formed to have a spiral or labyrinth structure.

22. The plasma processing apparatus according to claim 13, wherein the gas channels are disposed in a plural number in a longitudinal direction of the dielectric window, and are disposed at positions where the dielectric window in portions extending in the radial direction is even with respect to a longitudinal thickness.

23. The plasma processing apparatus according to claim 13, wherein the dielectric window is formed therein with a gas channel with the gas supply port and the gas introduction port at a position that overlaps the central region in a longitudinal direction.

24. A dielectric window constituting an upper part of a chamber of a plasma processing apparatus, the dielectric window comprising:
a plurality of gas channels extending in a radial direction of the dielectric window and each formed so that distances from a gas supply port connected to a gas supply section to gas introduction ports for introducing processing gas into the chamber are equal to each other, the gas supply section supplying the processing gas to the chamber,
wherein each of the gas introduction ports is provided at a position that overlaps a second surrounding region in a longitudinal direction with respect to an antenna assembly that is disposed above the chamber, is set with a central region, a first surrounding region surrounding the central region, and the second surrounding region surrounding the first surrounding region, and includes a coil disposed in the first surrounding region.
